(19) United States
(12) Patent Application Publication
(10) Pub. No.: US 2019/0144992 A1
(43) Pub. Date: May 16, 2019

(54) SPUTTERING APPARATUS AND METHOD OF OPERATING THE SAME

(71) Applicant: SAMSUNG ELECTRONICS CO., LTD., Suwon-si (KR)

(72) Inventors: Dong-Il Kim, Hwaseong-si (KR); Ki-Hwan RA, Seoul (KR); Seung-Hyuk KIM, Cheongju-si (KR)

(21) Appl. No.: 16/110,622

(22) Filed: Aug. 23, 2018

(30) Foreign Application Priority Data
Nov. 16, 2017 (KR) 10-2017-0153413

(51) Int. Cl. C23C 14/54; C23C 14/34; H01J 37/34

(52) U.S. Cl. CPC C23C 14/545; C23C 14/3492; H01L 21/2855; H01J 37/3464; H01J 37/3411

(57) ABSTRACT

A sputtering apparatus includes a sputtering chamber having a shield plate disposed on an inner surface thereof. A process controller controls a sputtering process performed in the sputtering chamber such that a deposition mode and a pasting mode for forming a cover layer on a sedimentary layer are conducted alternately with each other and a pasting time of the pasting mode increases in proportion to cumulative sputtering amounts.

### CROSS-REFERENCE TO RELATED APPLICATION

This application claims priority under 35 U.S.C § 119 to Korean Patent Application No. 10-2017-0153413, filed on Nov. 16, 2017 in the Korean Intellectual Property Office, the disclosure of which is incorporated by reference herein in its entirety.

### 1. TECHNICAL FIELD

Exemplary embodiments of the present inventive concept relate to a sputtering apparatus, and more particularly to a method of operating the same.

### 2. DISCUSSION OF RELATED ART

A conventional manufacturing method of semiconductor devices may include numerous repetitions of a deposition process and a patterning process and thus the pattern quality is largely influenced by the layer quality. Thus, the operation techniques of deposition apparatuses may have a relatively large effect on the pattern quality as well as the process conditions of the deposition process.

Various layer formation processes are used according to the composition and function of the thin layer. For example, a chemical vapor deposition (CVD) process, an atomic layer deposition (ALD) process and a sputtering process may be used for forming the thin layer. For example, since the sputtering process may have characteristics of relatively high deposition quality and relatively high thermal resistances of the thin layer, the sputtering process may be used for forming a qualified thin layer. In the conventional sputtering process, a gaseous plasma may be created from sputtering gases such as argon (Ar) gases as the sputtering plasma and then the ions of the sputtering plasma may be accelerated and collide onto a target plate. Source materials for the deposition may be eroded and ejected from the target in the form of neutral particles such as individual atoms and molecules, which may be referred to as deposition particles. The deposition particles may travel in a straight line and may come into contact with a substrate that is placed in the path of the particles, thus forming the thin layer on the substrate.

The deposition particles ejected from the target plate may effusively travel downwards from the target plate in the sputtering chamber, and thus the deposition particles may also come into contact with the inner sidewall of the sputtering chamber as well as with the substrate under the target plate. The deposition particles deposited onto the inner sidewall may be formed into an unexpected sedimentary layer on the sidewall of the sputtering chamber. The sedimentary layer in the sputtering chamber may generate contaminants in the layer formation process. Thus, an inner shield plate may be detachably installed along the inner sidewall of the chamber to cover a surface of the inner sidewall. The deposition particles generated from the target plate may be deposited onto the shield plate in place of the inner sidewall of the sputtering chamber, thus preventing the sidewall deposition of the sputtering chamber and forming a sedimentary layer on the shield plate. Then, the shield plate covered by the sedimentary layer may be exchanged with new one when exchanging the target plate for the maintenance of the sputtering apparatus.

The sedimentary layer may be gradually grown up on the shield plate until the shield plate is exchanged as the sputtering process is repeated. When the sedimentary layer is grown up to a thickness over a critical point on the shield plate, the sedimentary layer tends to be lifted from the shield plate and to be separated from the shield plate as sedimentary particles. The sedimentary particles may function as contaminants in a subsequent sputtering process.

Thus, a cover layer may be periodically formed on the sedimentary layer by a pasting process in such a way that the sedimentary layer is pasted to the shield plate and is prevented from being lifted from the shield plate. A plurality of the pasting processes may be repeated for a predetermined pasting time in the lifetime of the target plate.

The pasting time may be constant regardless of the repetition number of the sputtering processes or the cumulative sputtering amounts, so the sedimentary particles may gradually increase more and more as the sputtering process is repeated. For example, the cover layer may initially reduce or prevent lifting or separation of the sedimentary particles and the amount of the contaminants may gradually increase over time.

### SUMMARY

An exemplary embodiment of the present inventive concept provides a sputtering apparatus in which the thickness of the cover layer is proportional to the cumulative sputtering amounts, thus preventing a buildup of the sedimentary particles.

An exemplary embodiment of the present inventive concept provides a method of operating the sputtering apparatus.

According to an exemplary embodiment of the present inventive concept, a sputtering apparatus includes a sputtering chamber having a shield plate disposed on an inner surface thereof. A process controller controls a sputtering process performed in the sputtering chamber such that a deposition mode and a pasting mode for forming a cover layer on a sedimentary layer are conducted alternately with each other and a pasting time of the pasting mode increases in proportion to cumulative sputtering amounts.

According to an exemplary embodiment of the present inventive concept, a sputtering apparatus includes a sputtering chamber including a housing and a shield plate disposed on an inner surface of the housing. The sputtering chamber includes a substrate holder to which a substrate may be secured and a target plate from which deposition materials may be generated. A power source applies an electric power to the target plate. A gas supplier has a first supplier supplying sputtering gases into the sputtering chamber and a second supplier selectively supplying reaction gases into the sputtering chamber. A process controller controls a sputtering process performed in the sputtering chamber such that a deposition mode and a pasting mode for forming a cover layer on a sedimentary layer are conducted alternately with each other and a pasting time of the pasting mode increases in proportion to cumulative sputtering amounts.

According to an exemplary embodiment of the present inventive concept, a method of operating a sputtering apparatus includes conducting a deposition mode of a sputtering process to a substrate in a sputtering chamber. A shield plate is disposed on an inner surface of the sputtering chamber. The sputtering process is performed such that a thin layer is formed on the substrate together with a sedimentary layer on the shield plate. A cumulative number of deposited substrates on which the thin layer is formed is detected. An overall electric power applied to a target plate and a remaining life of the target plate is detected according to a deposition termination signal that is generated when the deposition mode to the substrate is completed. A pasting mode of the sputtering process is conducted for a pasting time in proportion to the overall electric power applied to the target plate when the cumulative number of the deposited substrates coincides with a substrate number of a substrate bundle that may be a process unit of the substrate for the sputtering process. A cover layer is formed on the sedimentary layer.

According to an exemplary embodiment of the present inventive concept, the cover layer may be formed on the sedimentary layer that may be formed on the shield plate disposed on the inner surface of the sputtering chamber together with the thin layer in such a way that the thickness of the cover layer may increase in proportion to the cumulative sputtering amounts. For example, the pasting time of the pasting mode for forming the over layer may become longer, while the operating time of the deposition mode for forming the thin layer and the sedimentary layer may be constant for increasing the thickness of the cover layer.

Thus, a presence of the contaminants caused by the sedimentary layer may be substantially prevented in the sputtering chamber and an occurrence of process defects may be reduced or eliminated in the sputtering process.

### BRIEF DESCRIPTION OF THE DRAWINGS

The above and other features of the present inventive concept will become more apparent by describing in detail exemplary embodiments thereof with reference to the accompanying drawings, in which:

FIG. 1 is a structural view of a sputtering apparatus according to an exemplary embodiment of the present inventive concept;

FIG. 2 is a timing chart of a deposition mode and a pasting mode in the sputtering apparatus of FIG. 1;

FIG. 3 is a cross-sectional view of a layer structure on a section A of the sputtering apparatus of FIG. 1; and

FIG. 4 is a flow chart of a method of operating the sputtering apparatus of FIG. 1 according to an exemplary embodiment of the present inventive concept.

### DETAILED DESCRIPTION OF THE EMBODIMENTS

Exemplary embodiments of the present inventive concept will be described below in more detail with reference to the accompanying drawings. In this regard, the exemplary embodiments may have different forms and should not be construed as being limited to the exemplary embodiments of the present inventive concept described herein.

Like reference numerals may refer to like elements throughout the specification and drawings.

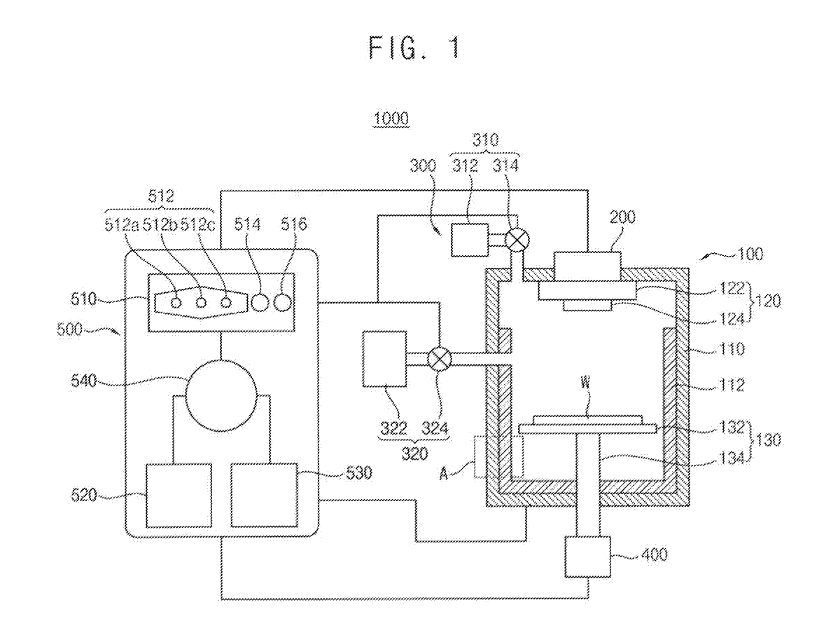

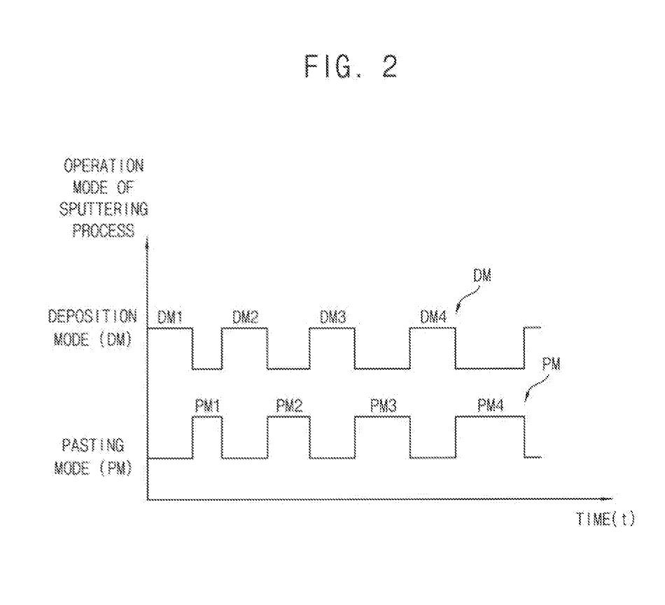

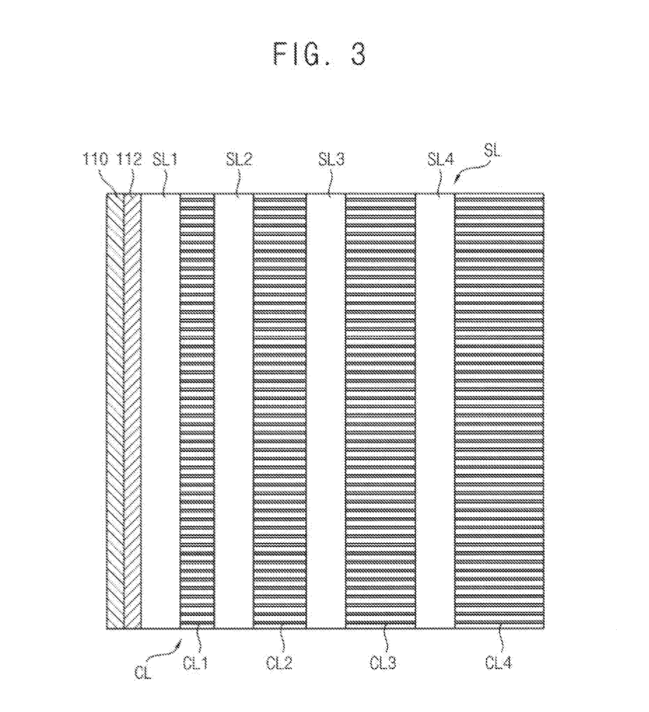

FIG. 1 is a structural view of a sputtering apparatus according to an exemplary embodiment of the present inventive concept. FIG. 2 is a timing chart of a deposition mode and a pasting mode in the sputtering apparatus of FIG. 1. FIG. 3 is a cross-sectional view of a layer structure on a section A of the sputtering apparatus of FIG. 1.

Referring to FIG. 1, a sputtering apparatus 1000 in accordance with an exemplary embodiment of the present inventive concept may include a sputtering chamber 100 having a shield plate 112. The shield plate 112 may be disposed on an inner surface of the sputtering chamber 100. The shield plate 112 may cover at least a portion o the inner surface of the sputtering chamber 100. In the sputtering chamber 100, a sputtering process may be conducted by a deposition mode DM to form a thin layer on a substrate W together with a sedimentary layer SL on the shield plate 112. A process controller 500 may control the sputtering process in such a way that the deposition mode DM and a pasting mode PM for forming a cover layer CL on the sedimentary layer SL may be conducted alternately with each other and a pasting time of the pasting mode may increase in proportion to cumulative sputtering amounts.

As an example, the sputtering chamber 100 may include a housing 110 having an inner space separated from an outside of the sputtering chamber 100. The housing 110 of the sputtering chamber 100 may have sufficient rigidity and stiffness for a vacuum pressure to be maintained in the sputtering chamber 100 (e.g., during the sputtering process). The inner space of the housing 110 may be under the vacuum pressure in the sputtering process. Thus, the sputtering chamber 100 may be a vacuum chamber having a deposition space isolated from surroundings and maintained under the vacuum pressure.

The shield plate 112 may be disposed on the inner surface of the housing 110, and thus deposition materials, which may be ejected from a target plate (e.g., target plate 124 described below in more detail) by sputtering plasma, may be prevented from being deposited onto the inner surface of the housing 110.

The deposition materials may fall down from an upper portion of the housing 110 and may radiate downwards from the target plate over the substrate W. Thus, the deposition materials may be deposited onto various surfaces of the substrate W. For example, the deposition materials may be deposited on side surfaces as well as an upper surface of the substrate W.

The deposition materials deposited onto any other surfaces except the substrate W (e.g., surfaces of the shield plate 112) may be formed into a sedimentary layer SL. A thickness of the sedimentary layer SL may increase as the sputtering process progresses. A relatively thick sedimentary layer may tend to be peeled or lifted off into sedimentary particles and the sedimentary particles may function as contaminants in the sputtering process.

The inner surface of the housing 110 around the substrate W may include the shield plate 112 disposed thereon. Thus, the deposition materials may be deposited onto a surface of the shield plate 112 in place of the inner surface of the housing 110. For example, the shield plate 112 may be detachably secured to the housing 110 and thus the shield plate 112 having accumulated the sedimentary layer SL may be replaced with a new shield plate 112, as described below in more detail. For example, the shield plate 112 may be replaced when the sedimentary layer SL reaches a predetermined thickness.

When the deposition materials are excessively deposited on the shield plate 112 and the thickness of the sedimentary layer SL reaches or exceeds a critical point, the sputtering apparatus 1000 may be stopped and the shield plate 112 having the relatively thick sedimentary layer SL may be exchanged with new one having no sedimentary layer. Thus, the sedimentary layer SL, which may function as a contaminant source in the sputtering process, may be removed from the sputtering chamber 100. Thus, by removing the contaminant source, a presence of the contaminants caused by the sedimentary layer SL may be substantially prevented in the sputtering chamber 100 and an occurrence of process defects may be reduced or eliminated in the sputtering process.

Since the deposition materials may fall down from an upper portion of the housing 110 and may radiate downwards from a target plate 124 over the substrate W, most of the sedimentary layer SL may be formed on a lower portion of the inner surface of the sputtering chamber 100. Thus, the shield plate 112 may be arranged on a bottom and a lower inner surface of the housing 110.

A target holder 120 may be arranged at a ceiling of the housing 110 and the target plate 124 may be secured to the target holder 120. Thus, the target holder 120 may be positioned at an opposite side of the sputtering chamber from the substrate W. A substrate holder 130 may be arranged at a bottom of the housing 110 and the substrate W may be secured to the substrate holder 130. The substrate holder 130 may be a stage (e.g., stage 132 described in more detail below). For example, the stage may include a metal or a plastic material. The stage may be coupled to a support column 134, which is described below in more detail. As an example, the substrate W may be secured to the substrate holder 130 by one or more screws or bolts.

The target holder 120 may include a base plate 122 that may be connected to a power source 200 and the target plate 124 may be secured to the base plate 122. As an example, the power source 200 may be a battery. Examples of a battery included in the power source may include a lithium ion battery. A cathode may be connected with the target plate 124 and an electric power may be applied to the target plate 124 through the cathode from the power source 200. The target plate 124 may include a bulk body comprising source materials of the sputtering process. When the ions of the sputtering plasma such as argon (Ar) gaseous plasma are accelerated and collide onto the target plate 124, the source materials for the sputtering process may be ejected from the target plate 124 in the form of atomic or molecular particles as the deposition materials.

Various target plates 124 may be allowable according to the thin layer on the substrate W. In an exemplary embodiment of the present inventive concept, the target plate 124 may include a metal plate comprising a relatively low resistance metal such as titanium (Ti), tantalum (Ta) or tungsten (W).

The substrate holder 130 may include a stage 132 on which the substrate W may be positioned (e.g., coupled) and a support column 134 supporting the stage 132. The support column 134 may be rotated with respect to a central axis thereof and may be linearly moved upwards and downwards (see, e.g., the pneumatic cylinder of the driver 400 described below in more detail). Thus, the stage 132 may be rotated and/or may be moved in an upward and downward direction (e.g., along a direction orthogonal to an upper surface of the driver 400). The vertical position of the stage 132 may be determined by the lift of the support column 134 and the horizontal position of the stage 132 may be determined by the rotation of the support column 134.

The target holder 120 may be connected to the power source 200 in such a configuration that the target plate 124 may be electrically connected to the power source 200 and may function as a cathode in the sputtering chamber 100. For example, the power source 200 may include a direct current (DC) power coil for applying a DC power to the target plate 124 and a radio frequency (RF) power coil for applying a RF power to the target plate 124. Sputtering gases in the sputtering chamber 100 may be transformed into the sputtering plasma by the DC power or the RF power.

A gas supplier 300 may be arranged at a side of the housing 110 and the sputtering gases and the reaction gases may be supplied into the sputtering chamber 100 by the gas supplier 300. The sputtering gases may be formed into the sputtering plasma for generating the deposition materials from the target plate 124 and the reaction gases may be reacted with the deposition materials on a surface of the substrate W to form the thin layer on the substrate W. For example, the gas supplier 300 may include a first supplier 310 for supplying the sputtering gases and a second supplier 320 for selectively supplying the reaction gases. The first supplier 310 and the second supplier 320 may be positioned at different sides of the housing 110. The gas supplier 300 may include a first air pump configured to selectively pass the reaction gas from a sputtering gas reservoir 312, through a first regulation valve 314 and into the sputtering chamber 100. The gas supplier 300 may include a second air pump configured to selectively pass the reaction gas from a reaction gas reservoir 322, through a second regulation valve 324 and into the sputtering chamber 100.

The first supplier 310 may include the sputtering gas reservoir 312 for storing the sputtering gases and the first regulation valve 314 for controlling the amount of the sputtering gases. The second supplier 320 may include the reaction gas reservoir 322 for storing the reaction gases and the second regulation valve 324 for controlling the amount of the reaction gases.

In an exemplary embodiment of the present inventive concept, the sputtering gas may include inactive gases such as argon (Ar) and the reaction gas may be variable according to the thin layer on the substrate W. For example, the reaction gas may include nitrogen (N) and a metal nitride layer may be formed on the substrate W as the thin layer.

The first and the second regulation valves 314 and 324 may be controlled by the process controller 500 for changing the process conditions and the operation mode of the sputtering process. The process controller 500 is described below in more detail.

The substrate holder 130 may be connected to the driver 400. The driver 400 may drive the substrate holder 130 to load the substrate W into the sputtering chamber 100, to unload the substrate W from the sputtering chamber 100 or to adjust the position of the substrate W in the sputtering chamber 100. As an example, the driver 400 may include a pneumatic cylinder configured to move the support column 134, thus moving the stage 132 coupled to the support column 134. The pneumatic cylinder may use the power of compressed gas to exert a force on the support column 134. Thus, the wafer W on the stage 132 may be moved by the driver. For example, the stage may be moved in an upward and downward direction (e.g., along a direction orthogonal to an upper surface of the driver 400).

The process controller 500 may control the power source 200 and the gas supplier 300 and may control the sputtering process in such a way that a deposition mode DM for forming the thin layer on the substrate W and a pasting mode PM for forming a covering layer CL on the shield plate 112 may be alternately conducted with each other in accordance with the process conditions in the sputtering chamber 100. For example, the process controller 500 may control the sputtering process in such a way that an operating time (e.g., a pasting time) of the pasting mode PM may gradually increase in proportion to overall deposition materials that may be sputtered onto the substrate W under the same target plate 124, which may be referred to as cumulative sputtering amounts. Thus, a removal (e.g., by lifting or pealing) of the sedimentary particles (e.g., contaminants) from the sedimentary layer SL on the shield plate 112 in the sputtering process may be reduced or eliminated. Thus, by removing the contaminant source, a presence of the contaminants caused by the sedimentary layer SL may be substantially prevented in the sputtering chamber 100 and an occurrence of process defects may be reduced or eliminated in the sputtering process.

When the deposition mode DM of the sputtering process is initiated by the process controller 500, the sputtering gases such as argon (Ar) gases may be supplied into the sputtering chamber 100 through the first supplier 310 and the reaction gases such as nitrogen (N₂) gases may be supplied into the sputtering chamber 100 through the second supplier 320. When completing the supply of the sputtering gases and the reaction gases, the sputtering gases may be formed into the sputtering plasma by an electric power (e.g., electric power provided by the power source 200) in the sputtering chamber 100. The ions of the sputtering plasma may collide to the target plate 124 and the deposition materials may be ejected from the target plate 124 in the form of atomic or molecular particles. The deposition materials may flow down toward the substrate W and may be deposited onto the substrate W by chemical reactions with the reaction gases, thus forming the thin layer on the substrate W. As an example, the process controller may be electrically connected to the first supplier 310, the second supplier 320 and the power source 200. The process controller may include a general purpose computer including a memory and a processor. The memory may store program instructions executable by the processor for carrying out the sputtering process (e.g., the deposition mode DM and the pasting mode PM) described herein, thus converting the general purpose computer to a special purpose computer configured to carry out the sputtering process described herein.

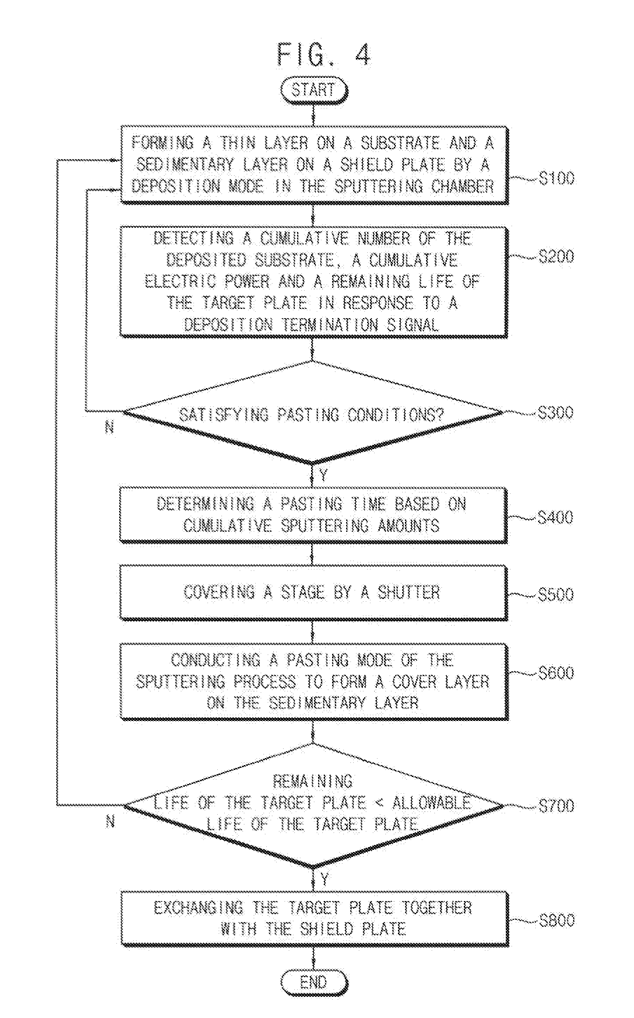

An exemplary algorithm executable by the processor is described in more detail below with reference to FIG. 4, in which a sputtering process in the sputtering chamber 100 is performed such that a deposition mode (e.g., DM) and a pasting mode (e.g., PM) forming a cover layer CL on a sedimentary layer SL alternately with each other, and in which a pasting time of the pasting mode increases in proportion to cumulative sputtering amounts.

Another exemplary algorithm executable by the processor for performing a sputtering process in the sputtering chamber 100 such that a deposition mode (e.g., DM) and a pasting mode (e.g., PM) forming a cover layer CL on a sedimentary layer SL alternately with each other, and in which a pasting time of the pasting mode increases in proportion to cumulative sputtering amounts includes the following steps. The algorithm includes conducting a deposition mode (e.g., DM) of a sputtering process to the substrate W in a sputtering chamber 100 in which the shield plate 112 is disposed on an inner surface of the sputtering chamber 100 such that a thin layer is formed on the substrate W together with a sedimentary layer (e.g., SL) on the shield plate 112. The algorithm includes detecting a cumulative number of deposited substrates on which the thin layer is formed, an overall electric power applied to the target plate 124 and a remaining life of the target plate 124 according to a deposition termination signal that is generated when the deposition mode (e.g., DM) to the substrate W is completed. The algorithm includes conducting a pasting mode (e.g., PM) of the sputtering process for a pasting time in proportion to the overall electric power applied to the target plate 124 when the cumulative number of the deposited substrates coincides with a substrate number of a substrate bundle that is a process unit of the substrate W for the sputtering process. Thus, a cover layer CL is formed on the sedimentary layer SL. The deposition mode is repeated with respect to each substrate in the substrate bundle and the pasting mode is repeated according to this exemplary embodiment when the cumulative number of the deposited substrates coincides with the substrate number of the substrate bundle until the target plate 124 is exchanged with a new target plate. The duration of each of the deposition mode and the pasting mode may be increased with each successive iteration of the deposition mode and the pasting mode (see, e.g., FIG. 3). Thus, a pasting time of the pasting mode may increase in proportion to cumulative sputtering amounts.

The deposition materials may also be deposited onto the shield plate 112 as well as the substrate W, so the sedimentary layer SL may be formed on the shield plate 112. When the layer characteristics (e.g., a thickness) of the sedimentary layer SL reaches or exceeds a predetermined reference point or a predetermined allowable range, the process controller 500 may stop the deposition mode temporarily and may initiate the pasting mode PM in such a way that a cover layer CL may be formed on the sedimentary layer SL.

For example, the process controller 500 may include a pasting unit 510 for generating a pasting signal (e.g., an electrical signal transmitted by the process controller 500) for conducting the pasting mode PM and setting up operation characteristics of the pasting mode PM, a parameter storing unit 520 (e.g., including a memory) for storing operation parameters of the sputtering process, a target exchanger 530 for detecting a remaining life of the target plate 124 and exchanging the target plate 124 together with the shield plate 112 according to the detected remaining life and a central control unit 540 for controlling the sputtering chamber 100, the power source 200 and the gas supplier 300 in such a way that the deposition mode DM and the pasting mode PM may be alternately conducted with each other.

The pasting unit 510 may include a signal generator 512 for generating the pasting signal (e.g., an electrical signal transmitted by the process controller 500) in accordance with a cumulative number of substrates on which the thin layer is formed (e.g., each substrate of the cumulative number of substrates may be referred to as deposited substrate), a sputtering amount detector 514 for detecting overall deposition materials up to the present deposition mode DM as cumulative sputtering amounts and a pasting timer 516 (e.g., a clock such as a digital clock) for determining the pasting time of the pasting mode PM in accordance with the detected cumulative sputtering amounts.

For example, the signal generator 512 may include an accumulator 512a for increasing the number of the deposited substrates in response to a deposition termination signal from the central control unit 540 whenever the deposition mode DM for the substrate(s) W is completed, a comparator 512b for comparing the cumulative number of the deposited substrates and the substrate number of a substrate bundle, and a pulse generator 512c for generating the pasting signal (e.g., an electrical signal transmitted by the process controller 500) as a digital pulse when the cumulative number of the deposited substrate may coincide with the substrate number of the substrate bundle.

When the deposition mode PM is completed for a single substrate in the sputtering chamber 100, a chamber control console may detect the process conditions of the sputtering chamber 100 and may generate the deposition termination signal. The deposition termination signal may be an electrical signal transmitted by the process controller 500. The deposition termination signal may be transferred to the central control unit 540 from the chamber control console.

The central control unit 540 may transfer the deposition termination signal to the signal generator 512 and the signal generator 512 may determine whether or not the deposition mode DM may be changed to the pasting mode PM in the sputtering chamber 100.

The deposition termination signal may be generated by each substrate W when the sputtering process is completed for each substrate. Thus, a single deposition termination signal indicates that a single deposition mode DM may be completed with respect to a single substrate and a single substrate may be formed into a single deposited substrate. Thus, the number of the deposited substrates may increase by one in the accumulator 512a whenever the signal generator 512 receives the deposition termination signal. In an exemplary embodiment of the present inventive concept, when the sputtering process is simultaneously conducted for a group of substrates, a single deposition termination signal indicates that a single deposition mode DM may be completed with respect to the group of the substrates. Thus, the number of the deposited substrate may increase by the substrate number of the group of substrates in the accumulator 512a when the signal generator 512 receives the deposition termination signal.

The number of the deposited substrates in the accumulator 512a may be compared with the substrate number of a substrate bundle which is a process unit of the substrate for the deposition mode DM. The substrate number of the substrate bundle may be set up as a process parameter of the sputtering process before operating the sputtering apparatus 1000. Thus, when the deposition mode DM is completed with respect to all of the substrates of the substrate bundle, the pasting mode PM may be conducted in the a sputtering chamber of the sputtering apparatus 1000 before initiating another deposition mode DM with respect to another substrate bundle.

For example, the substrate number of the substrate bundle may be determined as a cumulative number of the deposited substrates at which the amount or the density of the contaminant generated from the sedimentary layer SL may reach a maximal allowable point in the deposition mode DM. For example, the substrate number of the substrate bundle may indicate a maximal number of the substrates on condition that the contaminants generated from the sedimentary layer SL may be less than the allowable point for preventing the process defects of the sputtering process. As an example, the upper limit of the size of the sedimentary layer SL (before a pasting process is performed) may be based on a thickness of the sedimentary layer SL formed on the shield plate 112.

As an example, the substrate number of the substrate bundle may be set up to be constant under the same target plate 124, so each sedimentary layer SL may have substantially a same thickness when a plurality of the deposition modes DM may be conducted in the sputtering process as long as the target plate 124 need not be exchanged.

Thus, the contaminants generated from each sedimentary layer SL may be substantially uniform (e.g., may be relatively low or reduced to a predetermined level) due to having substantially a same thickness. Additionally, the contaminants may be accurately analyzed and controlled in each deposition mode DM under the same target plate 124. In an exemplary embodiment of the present inventive concept, the substrate number of the substrate bundle may be in a range of from about 200 to about 300. Thus, the pasting mode PM may be conducted at every time when the deposition mode DM may be completed with respect to about 200 to 300 substrates. For example, a pasting mode PM may be performed and a cover layer Cl may be generated each time a threshold number of 200 substrate thin films are formed. According to an exemplary embodiment of the present invention, a plurality of sedimentary layers SL and a plurality of cover layers may be alternatingly and repeatedly formed on the shield plate 112 before the shield plate 112 is ultimately replaced.

The substrate number of the substrate bundle may be varied according to the configurations of the sputtering chamber 100, the characteristics of the thin layer and the process conditions of the sputtering process. The substrate number of the substrate bundle may be stored in the parameter storing unit 520 of the process controller 500 (e.g., which may include a memory) as an operation parameter of the sputtering process.

When the cumulative number of the deposited substrates is changed or increased in the accumulator 512a, the comparator 512b may automatically retrieve the substrate number of the substrate bundle from the parameter storing unit 520 and the changed cumulative number of the deposited substrate from the accumulator 512a, and then may compare the increased cumulative number of the deposited substrate with the substrate number of the substrate bundle.

When the cumulative number of the deposited substrate is smaller than the substrate number of the substrate bundle, the pasting mode PM need not be entered in the sputtering chamber 100 since the contaminant density or amount caused by the sedimentary layer SL may be likely to be under an allowable point and thus the sputtering process may be conducted within predetermined parameters. Thus, the central control unit 540 may control the sputtering apparatus 1000 in such a way that the process mode may be still maintained as the deposition mode DM in the sputtering chamber 100. Thus, another substrate bundle may be loaded into the sputtering apparatus 1000 for the next sputtering process.

However, when the cumulative number of the deposited substrates meets or exceeds the substrate number of the substrate bundle, the contaminant density or amount caused by the sedimentary layer SL may be likely to be over the allowable point and the process defect may tend to occur if the sputtering process were to continue. In such a case, the signal generator 512 may generate the pasting signal for initiating the pasting mode PM. In response to the pasting signal, the deposition mode DM may be stopped and the pasting mode PM may start in the sputtering chamber 100 so as to form the cover layer CL on the sedimentary layer SL. Thus the contaminants from the sedimentary layer SL may be minimized by the cover layer CL. For example, the signal generator 512 may include a digital circuit device for generating the pulse signal as the pasting signal. However, the signal generator 512 may include an analogue circuit device for generating an analogue signal as the pasting signal.

In an exemplary embodiment of the present inventive concept, the sputtering amount detector 514 may detect the overall deposition materials up to the present deposition mode DM as the cumulative sputtering amounts when the deposition termination signal is generated.

While the substrates W of the substrate bundle may be unloaded from the sputtering chamber 100 when completing the deposition mode DM, the same shield plate 112 may be left in the sputtering chamber 100 without being replaced. For example, a same shield plate 112 may remain in the process chamber until the target plate 124 needs to be exchanged, and the shield plate 112 and the target plate 124 may be substantially simultaneously replaced (e.g., in a single continuous replacement process). Thus, the deposition materials (e.g., sedimentary layer LS) may be accumulated on the shield plate 112 alternately with the cover layer SL (see, e.g., FIG. 3) whenever the deposition mode DM is conducted. Thus, the contaminants may be isolated to the sedimentary layers SL that may be formed on the shield plate 112 alternately with the cover layer SL without lifting, pealing or otherwise removing the contaminants from the sedimentary layers SL. Thus, by removing the contaminant source, a presence of the contaminants caused by the sedimentary layer SL may be substantially prevented in the sputtering chamber 100 and an occurrence of process defects may be reduced or eliminated in the sputtering process.

In a conventional sputtering apparatus, the pasting time of the pasting mode is set up to be constant irrelevant to the repetition number of the deposition mode or the cumulative sputtering amounts, so each cover layer has substantially the same thickness when the pasting mode is repeated in the sputtering chamber. Accordingly, although each sedimentary layer may be covered by corresponding cover layer, the contaminant density in the sputtering chamber increases as the repetition number of the deposition mode increases although each sedimentary layer SL is covered by the corresponding cover layer.

However, according to an exemplary embodiment of the present inventive concept, the sputtering amount detector 514 may detect the cumulative sputtering amounts up to the present deposition mode DM in response to the deposition termination signal. The cumulative sputtering amounts may be detected by various methods.

For example, the cumulative sputtering amounts may be determined by an overall electric power that is consumed in the sputtering apparatus 1000. Since the sputtering amounts may be usually in proportion to the electric power that is applied to the power source 200 in the deposition mode DM, the cumulative sputtering amounts may be in proportion to overall electric powers that is applied to the power source 200 up to the present deposition mode from an initial deposition mode.

For example, the sputtering amount detector 514 may detect the overall electric power that is applied either from or to the power source 200 from an initial time when the target plate 112 is positioned in the sputtering chamber 100 to the present time when the deposition termination signal for the present deposition mode DM is generated. Thus, the detected overall electric power may be selected as the cumulative sputtering amounts.

The pasting timer 516 may determine the pasting time of the pasting mode PM in accordance with the cumulative sputtering amounts.

In an exemplary embodiment of the present inventive concept, the pasting time of the pasting mode PM may be determined by the following equation (1) in the pasting timer 516.

Tₚ=Tᵣ(1+aPₐ) (1)

In equation (1), Tₚ denotes the pasting time of the pasting mode, Tᵣ denotes a reference time of the pasting mode, a small letter ‘a’ denotes a proportional constant and Pₐ denotes the cumulative sputtering amounts.

As indicated in the above equation (1), the pasting time of the pasting mode PM may be in linear proportion to the cumulative sputtering amounts that may be detected from the cumulative electric powers. Thus, the pasting time of the pasting mode PM may increase as the deposition mode DM is repeated, and as a result, the thickness of the cover layer CL may increase as the pasting mode PM is repeated. As an example, each successive cover layer CL may become thicker along a direction moving away from the shield plate 112 (see, e.g., FIG. 3).

Referring to FIGS. 2 and 3, the operating time of the deposition mode DM may be substantially constant and the pasting time of the pasting mode PM may increase in the sputtering process having first to fourth deposition modes DM1 to DM4 and first to fourth pasting mode PM1 to PM4. A first to fourth sedimentary layers SL1 to SL4 may be individually formed in a respective deposition mode DM and a first to fourth cover layers CL1 to CL4 may be formed in a respective pasting mode PM. For example, each operating time of the first to fourth deposition modes DM 1 to DM4 may be substantially constant, and thus the first to fourth sedimentary layers SL1 to SL4 may have substantially a same thickness as each other Each pasting time of the first to fourth pasting modes PM1 to PM4 may linearly increase in such a way that the pasting time of the first pasting mode PM1 may be shortest and the pasting time of the fourth pasting mode PM4 may be largest, so that the thickness of the cover layer CL may increase from the first cover layer CL1 to the fourth cover layer CL4. Thus, each successive cover layer CL may become thicker along a direction moving away from the shield plate 112 (see, e.g., FIG. 3).

Thus, while the thickness of the sedimentary layer SL may be substantially constant in the sputtering chamber 100, the thickness of the cover layers CL may increase as the deposition mode DM is repeated in the sputtering chamber 100. In an exemplary embodiment of the present inventive concept, the fourth cover layer CL4 may have the largest thickness and the first cover layer CL1 may have the smallest thickness.

As an example, the more the deposition materials deposited to the shield plate 112, the greater the thickness of the cover layer CL. Thus, the contaminants may be minimized in the sputtering chamber 100 and a presence of the contaminants caused by the sedimentary layer SL may be substantially prevented in the sputtering chamber 100 and an occurrence of process defects may be reduced or eliminated in the sputtering process.

As an example, the proportional constant ‘a’ may include a chamber relevant constant that may be experimentally determined in a specified sputtering chamber. Repetition experiments may be conducted to the sputtering chamber 100 and the proportional constant ‘a’ may be determined as an appropriate value at which the contaminant density may be maintained under the allowable point. The proportional constant ‘a’ may be stored in the parameter storing unit 520 (e.g., which may include a memory) and may be entered by a user interface (e.g., a keyboard or a touch pad) of the sputtering apparatus 1000.

In an exemplary embodiment of the present inventive concept, the pasting timer 516 may call out the proportional constant ‘a’ from the parameter storing unit 520 and may determine the pasting time by equation (1) when the pasting signal is generated.

For example, the proportional constant ‘a’ may be in a range of from about 0.001 to about 0.005 and the reference time of the pasting mode PM may be set up in a range of from about 25 seconds to about 30 seconds. In addition, the overall electric power may be in a range of from about 1,500 KWh to about 1,800 KWh.

The pasting timer 516 may transfer the pasting time of the pasting mode PM to the central control unit 540, and then the central control unit 540 may change the operation mode of the sputtering process to the pasting mode PM from the deposition mode DM.

In an exemplary embodiment of the present inventive concept, the central control unit 540 may activate both of the first and the second suppliers 310 and 320 in the deposition mode DM and may activate only the first supplier 310 in the pasting mode PM.

For example, when forming a barrier metal layer for a gate electrode by the sputtering process, a bulk plate comprising titanium (Ti) may be provided with the sputtering chamber 100 as the target plate 112 and argon (Ar) gases and nitrogen (N) gases may be supplied into the sputtering chamber 100 as the sputtering gases and the reaction gases, respectively, through the gas supplier 300.

Thus, a titanium nitride (TiN) layer may be formed on the substrate W as the barrier metal layer and on the shield plate 112 as the sedimentary layer SL in the deposition mode DM of the sputtering process.

Then, the pasting signal may be transferred to the central control unit 540 together with the pasting time of the pasting mode PM, the central control unit 540 may control the sputtering apparatus 1000 in such a configuration that the first regulation valve 314 may be open and the second regulation valve 324 may be closed.

Due to the changes of the valve states of the first and the second regulation valves 314 and 324, titanium (Ti) materials in place of titanium nitride (TiN) may be deposited on the shield plate 112 in the sputtering chamber 100. When the deposition mode DM is completed, the substrate W may be unloaded from the sputtering chamber 100 and the stage 132 may be covered by a shutter in the pasting mode PM. Thus, the titanium (Ti) need not be deposited onto the substrate W or the stage 132 and may only be deposited onto the sedimentary layer SL including titanium nitride (TiN) as the cover layer CL for covering the sedimentary layer SL.

Thus, the sedimentary layer SL may be a titanium nitride (TiN) layer and the cover layer CL covering the sedimentary layer SL may be a titanium (Ti) layer.

The pasting mode PM may be conducted for the duration of the pasting time. When the pasting mode PM is completed, the target exchanger 530 may detect the remaining life of the target plate 124 and may compare the detected remaining life with an allowable life of the target plate 124.

For example, the physical and chemical properties of the target plate 124 may be detected whenever the deposition mode DM is completed and the remaining life of the target plate 124 may be determined from the detected physical and chemical properties. The remaining life may be transferred to the target exchanger 530 whenever the pasting mode PM is completed.

The allowable remaining life of the target plate 124 may be set up as a parameter of the sputtering process by a user interface (e.g., a keyboard or a touch pad) of the sputtering apparatus 1000 such as the substrate number of the substrate bundle.

When the detected remaining life of the target plate 124 is below the allowable life of the target plate 124, a target exchanging signal may be generated and transferred to the central control unit 540 by the target exchanger 530. When receiving the target exchanging signal, the central control unit 540 may stop the power source 200, the gas supplier 300 and the driver 400. Thereafter, the sputtering chamber 100 may be opened by the user.

Then, the target plate 124 of which the remaining life is below the allowable life may be exchanged with a new target plate 124. In addition, the shield plate 112 on which the sedimentary layer SL and the cover layer CL are alternately arranged with each other may also be exchanged with a new shield plate 112. Thus, the target plate 124 and the shield plate 112 may be exchanged at substantially a same time as each other (e.g., in a single continuous process).

When completing the exchange of the target plate 124 and the shield plate 112, the cumulative number of the deposited substrates in the accumulator 512a and the cumulative sputtering amounts in the sputtering amount detector 514 may be reset to ‘0’ by the target exchanger 530. For example, the cumulative number of the deposited substrates and the overall electric power that is applied to the target plate 124 may be reset whenever the target plate 124 is exchanged.

A method for operating the sputtering apparatus 1000 according to an exemplary embodiment of the present inventive concept is described in more detail below with reference to FIG. 4.

FIG. 4 is a flow chart of a method of operating the sputtering apparatus of FIG. 1 according to an exemplary embodiment of the present inventive concept.

Referring to FIGS. 1 and 4, the substrate W may be loaded into the sputtering chamber 100 in which the shield plate 112 is disposed on an inner surface and the deposition mode DM of the sputtering process may be conducted to the substrate W in the sputtering chamber 100 (step S100). Thus, the thin layer may be formed on the substrate W and the sedimentary layer SL may be formed on the shield plate 112.

The substrate W may be loaded into the sputtering chamber 100 and may be secured onto the substrate holder 130 and then the sputtering gases and the reaction gases may be supplied into the sputtering chamber 100 through the gas supplier 300. Electric power may be applied to the target holder 120 by the power source 200 and then the deposition mode DM of the sputtering process may be conducted in the sputtering chamber 100 in such a way that the thin layer and the sedimentary layer SL may be substantially simultaneously formed on the substrate W and on the shield plate 112, respectively.

When the deposition termination signal is applied to the central control unit 540, the cumulative number of the deposited substrate, the cumulative (e.g., overall) electric power applied to the target holder 120 and the remaining life of the target plate 124 (e.g., in response to the deposition termination signal) may be detected (step S200).

When the deposition materials are sufficiently deposited onto the substrate W and the thin layer is formed on the substrate W, the deposited substrate may be unloaded from the sputtering chamber 100. Then, the sputtering chamber 100 may be under standby state until another substrate is loaded into the sputtering chamber 100.

Then, the central control unit 540 may determine whether or not the deposition mode DM is changed to the pasting mode PM in the sputtering chamber 100 according to the pasting conditions. It may be determined whether the pasting conditions are satisfied (step S300).

The cumulative number of the deposited substrates, which may be counted by the accumulator 512a, may be compared with the substrate number of the substrate bundle, which may be stored in the parameter storing unit 520, in the pasting signal generator 512.

When the cumulative number of the deposited substrates is smaller than the substrate number of the substrate bundle, another substrate (e.g., substrate W) may be loaded into the sputtering chamber 100 and then another deposition mode DM may be conducted to the substrate in the sputtering chamber 100. However, when the cumulative number of the deposited substrates meets or exceeds the substrate number of the substrate bundle, the pasting signal generator 512 may generate the pasting signal and the operation mode of the sputtering process may be changed to the pasting mode PM from the deposition mode DM.

For example, the pasting mode PM may be conducted whenever the cumulative number of the deposited substrates meets or exceeds the substrate number of the substrate bundle.

When the pasting signal is generated by the pasting signal generator 512, the pasting time may be determined by the above equation (1) in the pasting timer 516 based on the cumulative sputtering amounts that may be detected from the overall electric power (step S400).

For example, the pasting time of the pasting mode PM may be in linear proportion to the cumulative sputtering amounts, so the thickness of the cover layer CL may increase as the pasting mode PM is repeated. Thus, as the repetition number of the deposition mode DM increases, the thickness of the cover layer CL may increase as indicated in equation (1), thus reducing or preventing the removal of contaminants from the sedimentary layer SL. Thus, by removing the contaminant source, a presence of the contaminants caused by the sedimentary layer SL may be substantially prevented in the sputtering chamber 100 and an occurrence of process defects may be reduced or eliminated in the sputtering process.

Then, the stage 132 from which the deposited substrate may be unloaded may be covered by the shutter (step S500) to protect the stage 132 from the pasting mode PM. Thus, the cover layer CL need not be formed on the stage 132 in the pasting mode PM.

The pasting mode PM may be conducted for the pasting time to form the cover layer CL on the sedimentary layer SL (step S600). As described above, the thickness of the cover layer CL may increase as the pasting mode PM is repeated (see, e.g., FIG. 3).

When the pasting mode PM is completed, the remaining life of the target plate 124 may be compared with the allowable life of the target plate 124 (step S700). Thus, it may be determined whether or not the target plate 124 and the shield plate 112 may be exchanged.

When the detected remaining life of the target plate 124 is smaller than the allowable life, the power source 200 and the gas supplier 300 may be stopped and the sputtering chamber 100 may be opened (e.g., by the user). Then, the target plate 124 and the shield plate 112 may be substantially simultaneously exchanged (step S800).

However, when the detected remaining life of the target plate 124 is greater than the allowable life, another substrate bundle may be transferred to the sputtering apparatus 1000 and the sputtering process may be conducted with respect to another substrate bundle without changing the target plate 124.

According to an exemplary embodiment of the present inventive concept, the cover layer CL may be formed on the sedimentary layer SL that is formed on the shield plate 112 for covering the inner surface of the sputtering chamber 100 together with the thin layer in such a way that the thickness of the cover layer CL increases in proportion to the cumulative sputtering amounts. For example, the pasting time of the pasting mode PM for forming the over layer CL may become longer, while the operating time of the deposition mode DM for forming the thin layer and the sedimentary layer SL may be substantially constant.

Therefore, the contaminants caused by the sedimentary layer SL may be reduced or prevented in the sputtering chamber 100 and process defects may be reduced or eliminated in the sputtering process.

While the present inventive concept has been shown and described with reference to the exemplary embodiments thereof, it will be apparent to those of ordinary skill in the art that various changes in form and detail may be made thereto without departing from the spirit and scope of the present inventive concepts.

What is claimed is:

1. A sputtering apparatus comprising:
a sputtering chamber having a shield plate disposed on an inner surface thereof; and
a process controller controlling a sputtering process performed in the sputtering chamber such that a deposition mode and a pasting mode forming a cover layer on a sedimentary layer are conducted alternately with each other and a pasting time of the pasting mode increases in proportion to cumulative sputtering amounts.

2. The sputtering apparatus of claim 1, wherein the pasting time of the pasting mode is determined by a following equation (1)
Tₚ=Tᵣ(1+aPₐ) (1),
wherein Tₚ denotes the pasting time of the pasting mode, Tᵣ denotes a reference time of the pasting mode, a small letter ‘a’ denotes a proportional constant and Pₐ denotes the cumulative sputtering amounts.

3. The sputtering apparatus of claim 2, wherein the cumulative sputtering amounts is determined by an overall electric power that has been applied to a target plate after the target plate is initially positioned in the sputtering chamber.

4. The sputtering apparatus of claim 3, wherein the proportional constant is in a range of 0.001 to 0.005 and the overall electric power is in a range of 1,500 KWh to 1,800 KWh.

5. The sputtering apparatus of claim 1, wherein the sputtering chamber includes a target plate to which ions of sputtering plasma are collided and providing deposition materials for the sputtering process and the process controller includes a target exchanger detecting a remaining life of the target plate and exchanging the target plate with a new target plate such that the shield plate is exchanged with a new shield plate together with the new target plate.

6. A sputtering apparatus comprising:
a sputtering chamber including a housing and a shield plate disposed on an inner surface of the housing, a substrate holder to which a substrate is secured and a target plate from which deposition materials are generated;
a power source applying an electric power to the target plate;
a gas supplier having a first supplier supplying sputtering gases into the sputtering chamber and a second supplier selectively supplying reaction gases into the sputtering chamber; and
a process controller controlling a sputtering process performed in the sputtering chamber such that a deposition mode and a pasting mode for forming a cover layer on a sedimentary layer are conducted alternately with each other and a pasting time of the pasting mode increases in proportion to cumulative sputtering amounts.

7. The sputtering apparatus of claim 6, wherein the process controller includes a pasting unit generating a pasting signal for conducting the pasting mode and setting up operation characteristics of the pasting mode, a parameter storing unit storing operation parameters of the sputtering process, a target exchanger detecting a remaining life of the target plate and exchanging the target plate together with the shield plate on a basis of the detected remaining life and a central control unit controlling the sputtering chamber, the power supplier and the gas supplier such that the deposition mode and the pasting mode are alternately conducted with each other.

8. The sputtering apparatus of claim 7, wherein the pasting unit includes a signal generator generating the pasting signal in accordance with a cumulative number of deposited substrates having a thin layer, a sputtering amount detector detecting overall deposition materials up to a present deposition mode DM as cumulative sputtering amounts, and a pasting timer determining the pasting time of the pasting mode in accordance with the cumulative sputtering amounts.

9. The sputtering apparatus of claim 8, wherein the signal generator includes an accumulator increasing the cumulative number of the deposited substrates in response to a deposition termination signal, a comparator comparing the cumulative number of the deposited substrate with a substrate number of a substrate bundle, and a pulse generator generating the pasting signal as a digital pulse when the cumulative number of the deposited substrate coincides with the substrate number of the substrate bundle.

10. The sputtering apparatus of claim 8, wherein the sputtering amount detector detects an overall electric power that has been applied to the target plate from an initial time after the target plate is positioned in the sputtering chamber and selects the overall electric power based on the cumulative sputtering amounts.

11. The sputtering apparatus of claim 10, wherein the pasting time of the pasting mode is determined by a following equation (1)
Tₚ=Tᵣ(1+aPₐ) (1),
wherein Tₚ denotes the pasting time of the pasting mode, Tᵣ denotes a reference time of the pasting mode, a small letter ‘a’ denotes a proportional constant and Pₐ denotes the cumulative sputtering amounts.

12. The sputtering apparatus of claim 11, wherein the proportional constant includes a chamber relevant constant that is experimentally determined in the sputtering chamber as a value at which a contaminant density is maintained under allowable predetermined point.

13. The sputtering apparatus of claim 12, wherein the proportional constant is in a range of 0.001 to 0.005, the pasting time is in a range of 25 seconds to 30 seconds and the overall electronic powers is in a range of 1,500 KWh to 1,800 KWh.

14. The sputtering apparatus of claim 7, wherein the central control unit controls the first supplier and the second supplier such that both of the first supplier and the second supplier are activated in the deposition mode and the first supplier is activated together with stopping the second supplier in the pasting mode.

15. The sputtering apparatus of claim 14, wherein the central control unit activates the pasting unit in response to a deposition termination signal that is generated when the deposition mode to the substrate is completed and stops the operation of the second supplier in response to a pasting signal that is generated when the pasting mode is initiated.

16. A method of operating a sputtering apparatus, comprising:
conducting a deposition mode of a sputtering process to a substrate in a sputtering chamber in which a shield plate is disposed on an inner surface of the sputtering chamber such that a thin layer is formed on the substrate together with a sedimentary layer on the shield plate;
detecting a cumulative number of deposited substrates on which the thin layer is formed, an overall electric power applied to a target plate and a remaining life of the target plate according to a deposition termination signal that is generated when the deposition mode to the substrate is completed; and
conducting a pasting mode of the sputtering process for a pasting time in proportion to the overall electric power applied to the target plate when the cumulative number of the deposited substrates coincides with a substrate number of a substrate bundle that is a process unit of the substrate for the sputtering process, and forming a cover layer on the sedimentary layer.

17. The method of claim 16, wherein the deposition mode is repeated with respect to each substrate in the substrate bundle and the pasting mode is repeated at every time when the cumulative number of the deposited substrates coincides with the substrate number of the substrate bundle until the target plate is exchanged with a new target plate.

18. The method of claim 16, wherein the pasting time of the pasting mode is determined by a following equation (1)
Tₚ=Tᵣ(1+aPₐ) (1),
wherein Tₚ denotes the pasting time of the pasting mode, Tᵣ denotes a reference time of the pasting mode, a small letter ‘a’ denotes a proportional constant and Pₐ denotes the cumulative sputtering amounts.

19. The method of claim 16, further comprising:
detecting a remaining life of the target plate; and
comparing the remaining life of the target plate with an allowable life.

20. The method of claim 19, wherein the target plate and the shield plate are exchanged with a new target plate and a new shield plate, respectively, when the remaining life is smaller than the allowable life of the target plate.
